(19) United States
(12) Patent Application Publication
(10) Pub. No.: US 2015/0303105 A1
(43) Pub. Date: Oct. 22, 2015

(54) METHOD AND APPARATUS FOR MANUFACTURING SEMICONDUCTOR DEVICE

(71) Applicant: TOKYO ELECTRON LIMITED, Minato-ku, Tokyo (JP)

(72) Inventors: Haruo IWATSU, Kumamoto (JP); Toshiyuki MATSUMOTO, Kumamoto (JP)

(21) Appl. No.: 14/648,386

(22) PCT Filed: Nov. 28, 2013
(86) PCT No.: PCT/JP2013/082032

§ 371 Date: May 29, 2015

(30) Foreign Application Priority Data
Nov. 29, 2012 (JP) 2012-260701

(51) Int. Cl. H01L 21/768; C25D 21/12; C25D 5/02; C25D 7/12

(52) U.S. Cl. CPC H01L 21/76879; C25D 7/12; C25D 21/12; C25D 5/026

(57) ABSTRACT

Disclosed is a method for manufacturing a semiconductor device. The method includes a template disposing step, a processing solution supply step, and a processing step. At the processing step, a template including a plurality of flow paths configured to allow a processing solution to flow therethrough and a plurality of electrodes installed in the flow paths is disposed with respect to a substrate including a plurality of through holes formed therethrough in a thickness direction such that the flow paths correspond to the through holes. At the processing solution supply step, the processing solution is supplied into the through holes through the flow paths, and at the processing step, a predetermined processing is performed with respect to the substrate by applying a voltage using one of the electrodes as a positive electrode and using another electrode as a negative electrode.

### TECHNICAL FIELD

This application is based on and claims priority from Japanese Patent Application No. 2012-260701, filed on Nov. 29, 2012, with the Japan Patent Office, the disclosure of which is incorporated herein by reference.

The present invention relates to a semiconductor device manufacturing method and a semiconductor device manufacturing device.

### BACKGROUND

Recently, high performance of a semiconductor device is required and high integration of semiconductor elements is in progress. Under this circumstances, when a semiconductor device is manufactured by disposing a plurality of highly-integrated semiconductor elements within a horizontal plane and interconnecting the semiconductor elements with wiring lines, the length of the wiring lines increases. Thus, there is a fear that the resistance of the wiring lines becomes larger and the wiring delay increases.

Thus, there has been proposed a three-dimensional integration technique that laminates semiconductor elements three-dimensionally. In the three-dimensional integration technique, a plurality of electrodes called penetration electrodes (TSV: Through Silicon Vias), which has a small diameter of, e.g., 100 μm or less, is formed so as to penetrate a semiconductor wafer (hereinafter referred to as a “wafer”) which is made thin by polishing the rear surface thereof and which has a plurality of circuits formed on the front surface thereof. Wafers laminated one on another are electrically connected via the penetration electrodes (see. e.g., Patent document 1).

Various methods for forming the aforementioned penetration electrodes have been studied. For example, it has been proposed to form penetration electrodes by performing electrolytic plating within, e.g., through holes of a wafer, using a template provided with flow paths of, e.g., plating solution (see, e.g., Patent Document 2). Specifically, after the template is first disposed to face the wafer, the plating solution is supplied from the flow paths of the template into the through holes of the wafer. Thereafter, a voltage is applied using a template side electrode as a positive electrode and using a wafer side opposite electrode as a negative electrode. Penetration electrodes are formed within the through holes by performing a plating process within the through holes.

### PRIOR ART DOCUMENT

### Patent Document

Patent Document 1: Japanese Patent Laid-Open Publication No. 2009-004722

Patent Document 2: Japanese Patent Laid-Open Publication No. 2011-243768

### SUMMARY OF THE INVENTION

### Problems to be Solved

However, in order to perform the electrolytic plating using the template as disclosed in Patent Document 2, an opposite electrode needs to be provided at the wafer side. For example, when the opposite electrode is formed in a support substrate supporting a thinned wafer, the device configuration becomes complex and large-scale. Furthermore, for example, when a seed layer of a wafer is used as an opposite electrode, a plated layer is formed on the entire front surface of the wafer. Therefore, the plated layer formed in the portions other than the inside of through holes needs to be removed by, e.g., chemical mechanical polishing (CMP). Thus, there is a room for improvement in the throughput of a plating process.

Furthermore, in the manufacturing process of the semiconductor device, after the penetration electrodes are formed as described above, electrical tests for the penetration electrodes and the circuits of the wafer are conducted. For example, the wafer side opposite electrode becomes a common electrode with respect to all the penetration electrodes. Therefore, when one attempts to conduct electrical tests for the penetration electrodes and the electronic circuits in this state, all the penetration electrodes are brought into a short-circuited state, which enables the electrical tests to be conducted. For that reason, in order to conduct the electrical tests, it is necessary to additionally perform a step of removing the opposite electrode. Accordingly, there is a room for improvement in the throughput of the manufacturing process of the semiconductor device.

The present invention has been made in view of such points. It is an object of the present invention to improve the throughput of a manufacturing process of a semiconductor device while reducing the manufacturing cost of the semiconductor device.

### Means to Solve the Problems

In order to accomplish the objects described above, the present invention provides a method for manufacturing a semiconductor device. The method includes: a template disposing step at which a template including a plurality of flow paths configured to allow a processing solution to flow therethrough and a plurality of electrodes installed in the flow paths is disposed, with respect to a substrate including a plurality of through holes formed therethrough in a thickness direction such that the flow paths correspond to the through holes; a processing solution supply step at which the processing solution is supplied into the through holes through the flow paths; and a processing step at which a predetermined processing is performed with respect to the substrate by applying a voltage using one of the electrodes as a positive electrode and using another electrode as a negative electrode.

According to the present invention, by applying a voltage using one of the electrodes of the template as a positive electrode and using another electrode as a negative electrode, an electrolysis process may be performed with the processing solution existing within the through holes and to perform specified processing with respect to the substrate. Accordingly, there is no need to install an opposite electrode at the wafer side as is the case in the prior art, so that the apparatus configuration may be simplified and the manufacturing cost of the semiconductor device may be reduced. Furthermore, the specified processing may be performed only within the through holes, thereby improving the throughput of the specified processing of the substrate. Moreover, there is no need to install an opposite electrode common to the penetration electrodes (the plating solution existing within the through holes). Therefore, the penetration electrodes may be electrically independent from each other. In that state, an electrical test for the penetration electrodes and the circuits of the substrate may be performed. Accordingly, when conducting an electrical test as is the case in the prior art, for example, the step of removing an opposite electrode may be omitted and thus, the throughput of the manufacturing process of the semiconductor device may be improved.

According to another aspect, the present invention provides an apparatus for manufacturing a semiconductor device. The apparatus includes: a template including a plurality of flow paths configured to allow a processing solution to flow therethrough and a plurality of electrodes installed in the flow paths; and a control unit configured to control the template to execute: a template disposing step at which, with respect to a substrate including a plurality of through holes formed therethrough in a thickness direction, the template is disposed such that the flow paths correspond to the through holes; a processing solution supply step at which the processing solution is supplied into the through holes through the flow paths; and a processing step at which a predetermined processing is performed with respect to the substrate by applying a voltage using one of the electrodes as a positive electrode and using another electrode as a negative electrode.

### Effect of the Invention

According to the present invention, the throughput of a semiconductor device manufacturing process of may be improved while reducing the manufacturing cost of the semiconductor device.

### BRIEF DESCRIPTION OF THE DRAWINGS

FIG. 1 is a vertical sectional view schematically illustrating a configuration of a wafer according to an exemplary embodiment.

FIG. 2 is an explanatory view of an input gate and an electrostatic protection circuit of a wafer.

FIG. 3 is an explanatory view illustrating a state in which a support substrate is installed in a wafer.

FIG. 4 is an explanatory view illustrating a state in which a wafer is thinned.

FIG. 5 is an explanatory view illustrating a state in which through holes are formed in a wafer.

FIG. 6 is an explanatory view illustrating a state in which a template (manufacturing device) is installed in a wafer.

FIG. 7 is an explanatory view illustrating a state in which a plating solution is supplied to through holes via flow paths.

FIG. 8 is an explanatory view illustrating a state in which a voltage is applied using grounding electrodes as positive electrodes and using power source electrodes as negative electrodes.

FIG. 9 is an explanatory view illustrating a state in which penetration electrodes are formed within grounding through holes.

FIG. 10 is an explanatory view illustrating a state in which a voltage is applied using one power source electrode as a positive electrode and using the other power source electrode as a negative electrode.

FIG. 11 is an explanatory view illustrating a state in which penetration electrodes are formed within power source through holes.

FIG. 12 is an explanatory view illustrating a state in which a voltage is applied using signal electrodes as positive electrodes and using power source electrodes as negative electrodes.

FIG. 13 is an explanatory view illustrating a state in which penetration electrodes are formed within signal through holes.

FIG. 14 is an explanatory view illustrating a state in which bumps are formed on penetration electrodes.

FIG. 15 is an explanatory view illustrating a state in which a semiconductor device is manufactured.

FIG. 16 is an explanatory view illustrating a state in which, in another exemplary embodiment, a voltage is applied using one grounding electrode as a positive electrode and using the other grounding electrode as a negative electrode.

FIG. 17 is an explanatory view illustrating a state in which, in another exemplary embodiment, penetration electrodes are formed within grounding through holes.

FIG. 18 is a vertical sectional view schematically illustrating a configuration of a wafer according to another exemplary embodiment.

FIG. 19 is an explanatory view of an output circuit.

FIG. 20 is an explanatory view illustrating a state in which resistors of an output circuit are conceptualized into protection diodes.

FIG. 21 is an explanatory view illustrating a state in which, in another exemplary embodiment, a voltage is applied using signal electrodes as positive electrodes and using power source electrodes as negative electrodes.

FIG. 22 is an explanatory view illustrating a state in which, in another exemplary embodiment, penetration electrodes are formed within signal through holes.

### DETAILED DESCRIPTION TO EXECUTE THE INVENTION

Hereinafter, exemplary embodiments of the present invention will be described. In the exemplary embodiments, a semiconductor device manufacturing method according to the present invention will be described together with a configuration of a semiconductor device manufacturing apparatus used in the manufacturing method. In the drawings used in the following description, for the purpose of giving priority to the easy understanding of the technology, the dimensions of individual components may not necessarily correspond to actual dimensions.

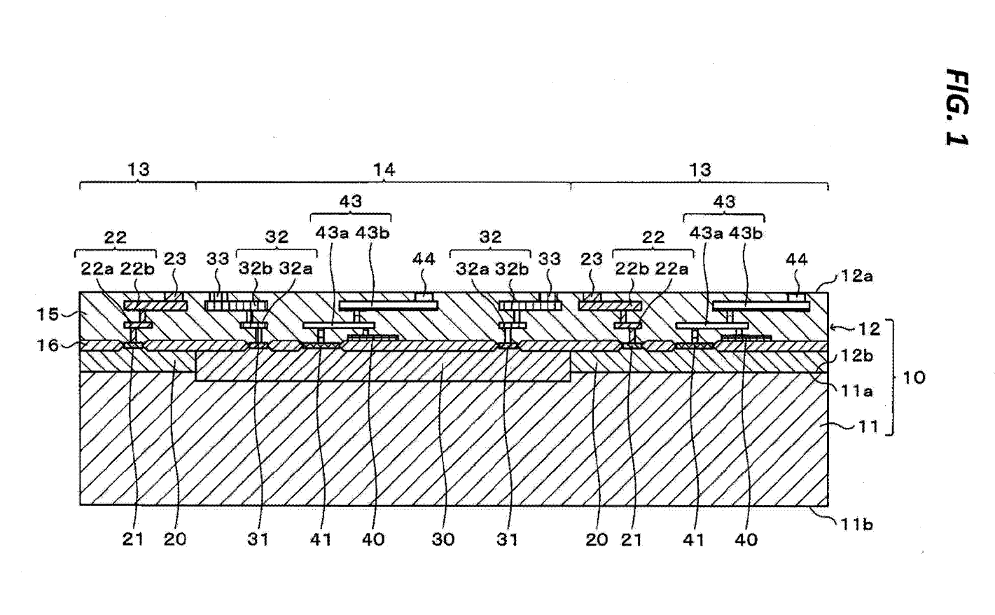

First, as illustrated in FIG. 1, in a wafer 10 as a substrate, a device layer 12 is formed on, e.g., a bulk layer 11. Hereinafter, the surface of the bulk layer 11 existing at the side of the device layer 12 will be referred to as a front surface 11a. The surface of the bulk layer 11 existing at the opposite side from the device layer 12 will be referred to as a rear surface 11b. Furthermore, the surface of the device layer 12 existing at the opposite side from the bulk layer 11 will be referred to as a front surface 12a. The surface of the device layer 12 existing at the side of the bulk layer 11 will be referred to as a rear surface 12b.

The bulk layer 11 is formed of P-type silicon. For example, a CMOS formed by combining an N-type MOS transistor 13 and a P-type MOS transistor 14 is formed in the device layer 12. In the device layer 12, a field oxide film 16 is formed between an insulation film 15 and a P-well 20 and an N-well 30.

The N-type MOS transistor 13 includes a diffusion region formed of the P-well 20. A P⁺ layer 21 connected to a ground is formed in the P-well 20. A grounding line 22 formed in the insulation film 15 is connected to the P⁺ layer 21. The grounding line 22 includes a first metal 22a connected to the P⁺ layer 21 via a wiring line and a second metal 22b connected to the first metal 22a via a wiring line. The second metal 22b is connected to a bump 23 exposed on the front surface 12a of the device layer 12.

In the illustrated example, one set of the P⁺ layer 21, the grounding line 22, and the bump 23 is formed in the N-type MOS transistor 13. However, in reality, plural sets of the P⁺ layers 21, the grounding lines 22 and the bumps 23 are formed in the N-type MOS transistor 13.

The P-type MOS transistor 14 includes a diffusion region formed of the N-well 30. An N⁺ layer 31 connected to a power source is formed in the N-well 30. A power source line 32 formed in the insulation film 15 is connected to the N⁺ layer 31. The power source line 32 includes a first metal 32a connected to the N⁺ layer 31 via a wiring line and a second metal 32b connected to the first metal 32a via a wiring line. The second metal 32b is connected to a bump 33 exposed on the front surface 12a of the device layer 12.

In the illustrated example, two sets of the N⁺ layers 31, the power source lines 32, and the bumps 33 are formed in the P-type MOS transistor 14. However, the number of the N⁺ layers 31, the power source lines 32, and the bumps 33 is not limited thereto but may be arbitrarily set.

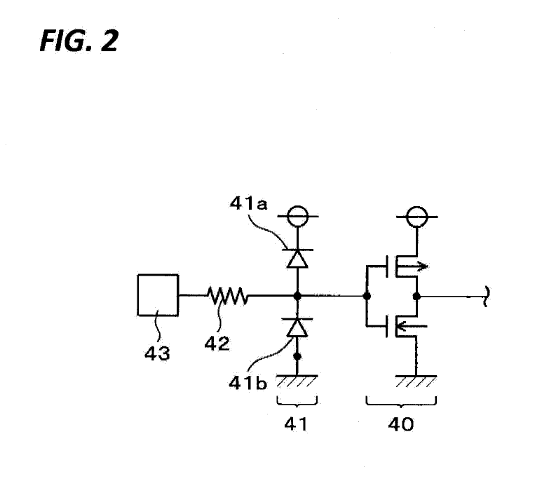

Each of the N-type MOS transistor 13 and the P-type MOS transistor 14 includes an input gate 40 formed in the insulation film 15 so that a signal is inputted to the input gate 40 and an electrostatic protection circuit 41 formed in the P-well 20 or the N-well 30. As illustrated in FIG. 2, in order to avoid electro-static discharge (ESD) of the input gate 40, the electrostatic protection circuit 41 includes a protection diode 41a connected to the power source side (the power source line 32) and a protection diode 41b connected to the ground side (the grounding line 22). The electrostatic protection circuit 41 is connected to the input gate 40. In order to protect the input gate 40 when a voltage exceeding a predetermined voltage is inputted from a signal line 43 to be described later, a current is allowed to flow toward the power source or the ground via the electrostatic protection circuit 41. A protection resistor 42 for controlling the current flowing through the input gate 40 is provided between the signal line 43 and the electrostatic protection circuit 41.

As illustrated in FIG. 1, the signal line 43 formed in the insulation film 15 is connected to the electrostatic protection circuit 41. The signal line 43 includes a first metal 43a connected to the electrostatic protection circuit 41 via a wiring line and a second metal 43b connected to the first metal 43a via a wiring line. The second metal 43b is connected to a bump 44 exposed on the front surface 12a of the device layer 12.

While not shown in the drawings, other wiring lines, circuits and electrodes are formed in the device layer 12,

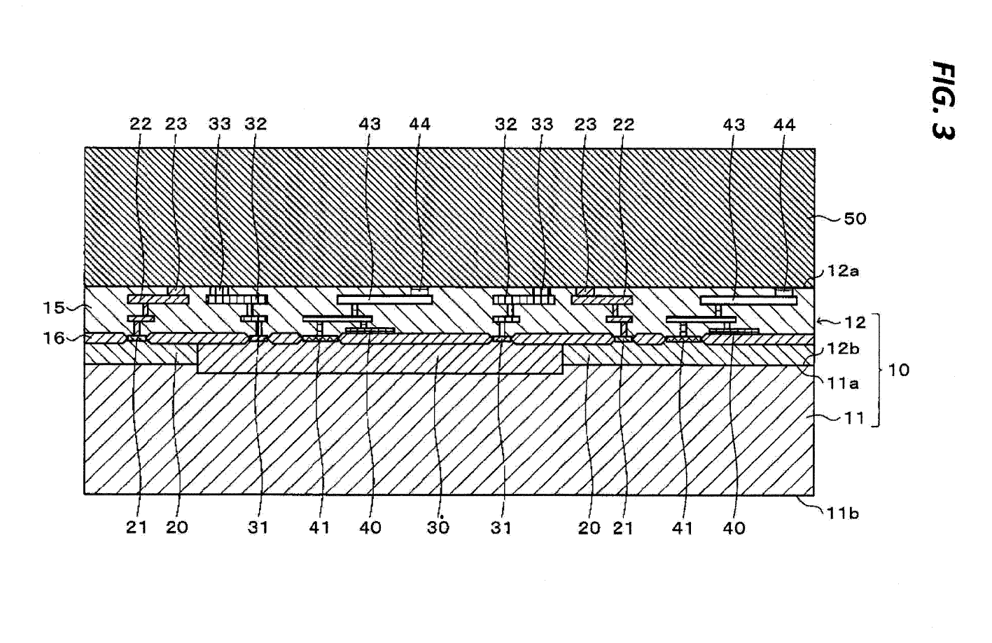

Once the device layer 12 is formed on the bulk layer 11 in the aforementioned manner, a support substrate 50 is installed on the front surface 12a of the device layer 12 as illustrated in FIG. 3. The support substrate 50 is disposed to cover the front surface 12a of the device layer 12. The support substrate 50 is bonded to the device layer 12 by, e.g., a releasable adhesive. A silicon wafer or a glass substrate is used as the support substrate 50.

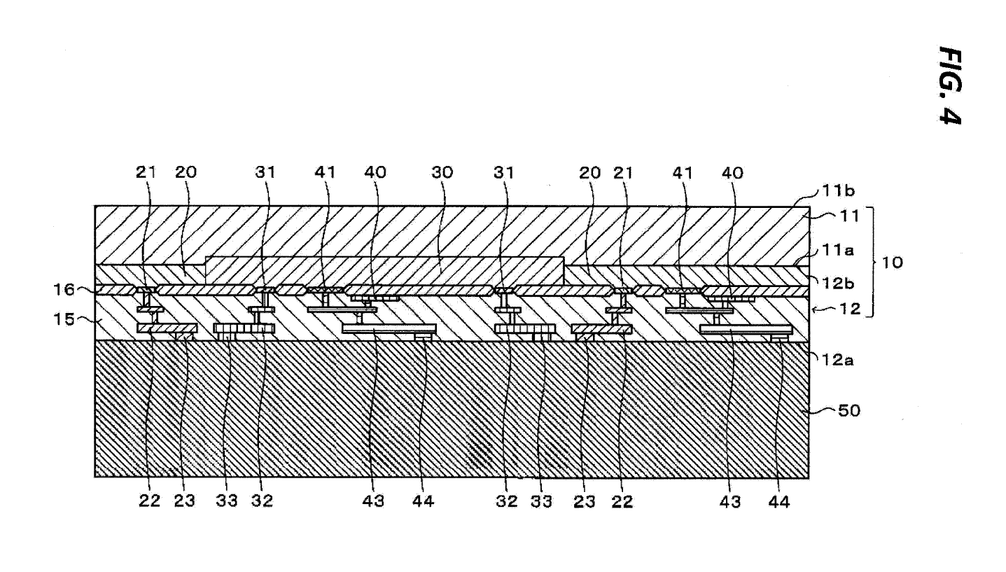

Thereafter, the rear surface 11b of the bulk layer 11 is polished as illustrated in FIG. 4, thereby making the wafer 10 thin. At this step, the device layer 12 is disposed below the bulk layer 11 by inverting the front and rear surfaces of the wafer 10. After this step, the subsequent steps are performed in the state in which the wafer 10 is made thin. Since the support substrate 50 gives sufficient strength to the wafer 10, the wafer 10 may be prevented from cracking during the transfer thereof.

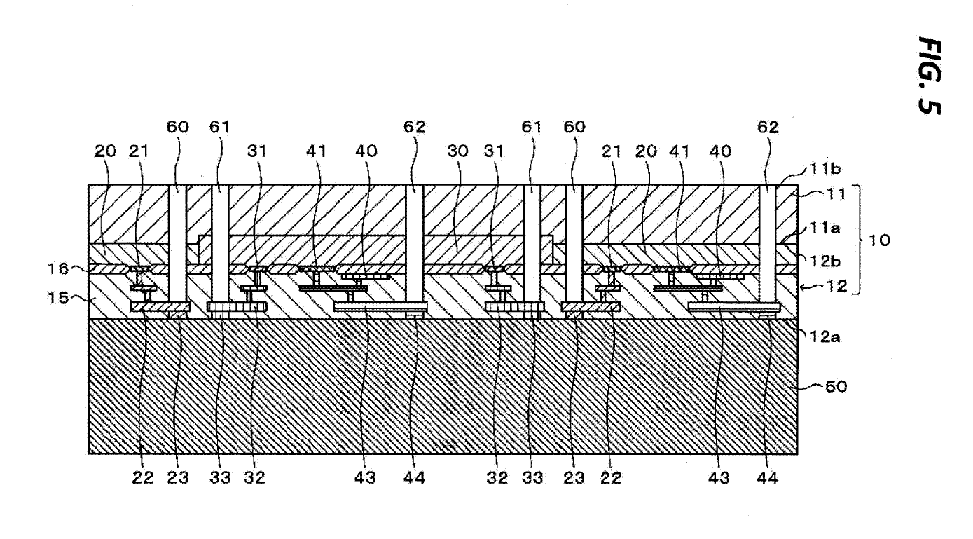

Thereafter, a plurality of through holes 60 to 62 penetrating the wafer 10 in the thickness direction is formed as illustrated in FIG. 5. While the through holes 60 to 62 do not completely penetrate wafer 10, such a name is given to the through holes 60 to 62 because penetration electrodes 80 to 82 formed within the through holes 60 to 62 electrically interconnect the front surface 12a and the rear surface 11b of the wafer 10. More specifically, the through holes 60 to 62 penetrate the bulk layer 11 of the wafer 10 in the thickness direction. In the device layer 12, the through holes 60 to 62 are formed to extend to the positions where the through holes 60 to 62 reach the grounding line 22, the power source line 32, and the signal line 43, respectively. Hereinafter, the through hole 60 formed at the position corresponding to the grounding line 22 will be referred to as a grounding through hole 60. The through hole 61 formed in the position corresponding to the power source line 32 will be referred to as a power source through hole 61. The through hole 62 formed at the position corresponding to the signal line 43 will be referred to as a signal through hole 62.

The through holes 60 to 62 may be simultaneously formed by, e.g., a photolithography process and an etching process. Alternatively, the through holes 60 to 62 may be formed by supplying an etching solution onto the wafer 10 using a template 71 to be described later, applying a voltage to the etching solution, and electrolytically etching the wafer 10.

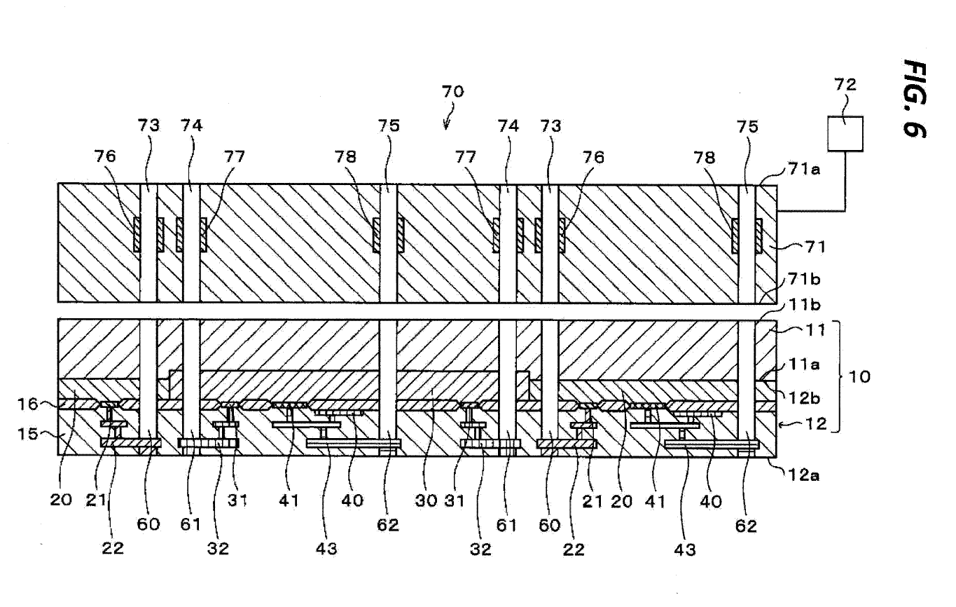

Thereafter, a plating process is performed within the through holes 60 to 62 using the semiconductor device manufacturing apparatus. As illustrated in FIG. 6, the manufacturing apparatus 70 includes a template 71 and a control unit 72 that controls the template 71. In FIG. 6 and the subsequent figures, for the purpose of giving priority to the easy understanding of the technology, the illustration of the support substrate 50 installed in the wafer 10 is omitted.

The template 71 has, e.g., a substantially disc-like shape, and has the same shape as the plan-view shape of the wafer 10. For example, silicon carbide (SiC) is used for the template 71.

A plurality of flow paths 73 to 75 for allowing a plating solution as a processing solution to flow therethrough is formed in the template 71. The flow paths 73 to 75 are respectively formed at the positions where the flow paths 73 to 75 face the through holes 60 to 62 of the wafer 10 when the template 71 is disposed at the side of the rear surface 11b of the wafer 10. The flow paths 73 to 75 penetrate the template 71 in the thickness direction to extend from the front surface 71a of the template 71 to the rear surface 71b thereof. The opposite end portions of the flow paths 73 to 75 are opened. Electrodes 76 to 78 are respectively installed on the side surfaces of the flow paths 73 to 75.

Hereinafter, the flow path 73 facing the grounding through hole 60 will be referred to as a grounding flow path 73 and the electrode installed in the grounding flow path 73 will be referred to as a grounding electrode 76. The flow path 74 facing the power source through hole 61 will be referred to as a power source flow path 74 and the electrode installed in the power source flow path 74 will be referred to as a power source electrode 77. The flow path 75 facing the signal through hole 62 will be referred to as a signal flow path 75 and the electrode installed in the signal flow path 75 will be referred to as a signal electrode 78.

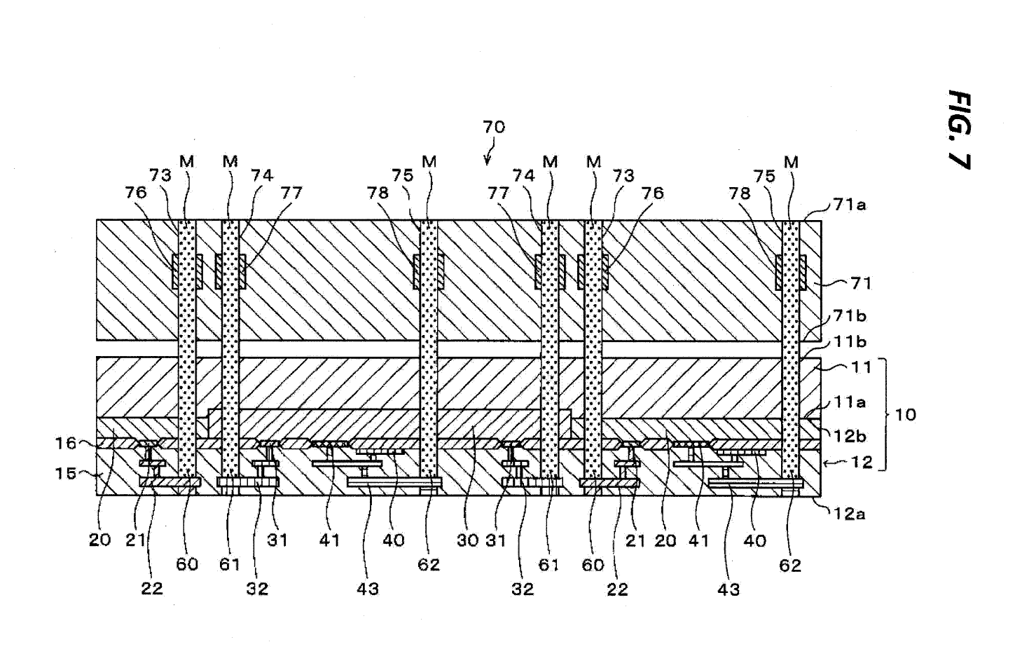

Then, the template 71 of such a configuration is disposed at the side of the rear surface 11 of the wafer 10. Thereafter, as illustrated in FIG. 7, a plating solution M is supplied to the through holes 60 to 62 through the flow paths 73 to 75. Thus, the plating solution M is filled in each of the flow paths 73 to 75 and the through holes 60 to 62. As for the plating solution M, e.g., a mixed solution (electrolytic copper plating solution), obtained by dissolving copper sulfate and sulfuric acid, may be used.

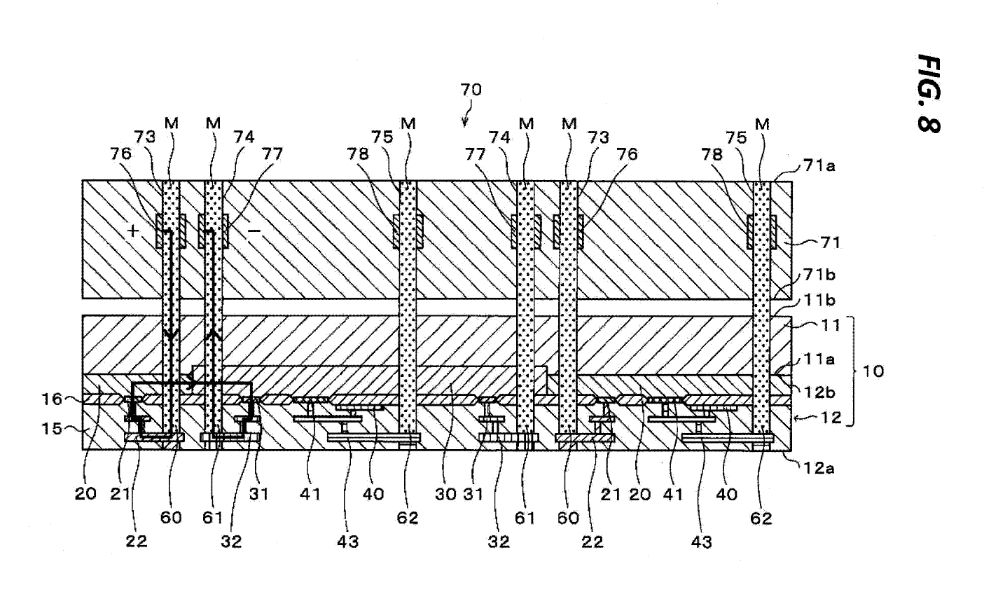

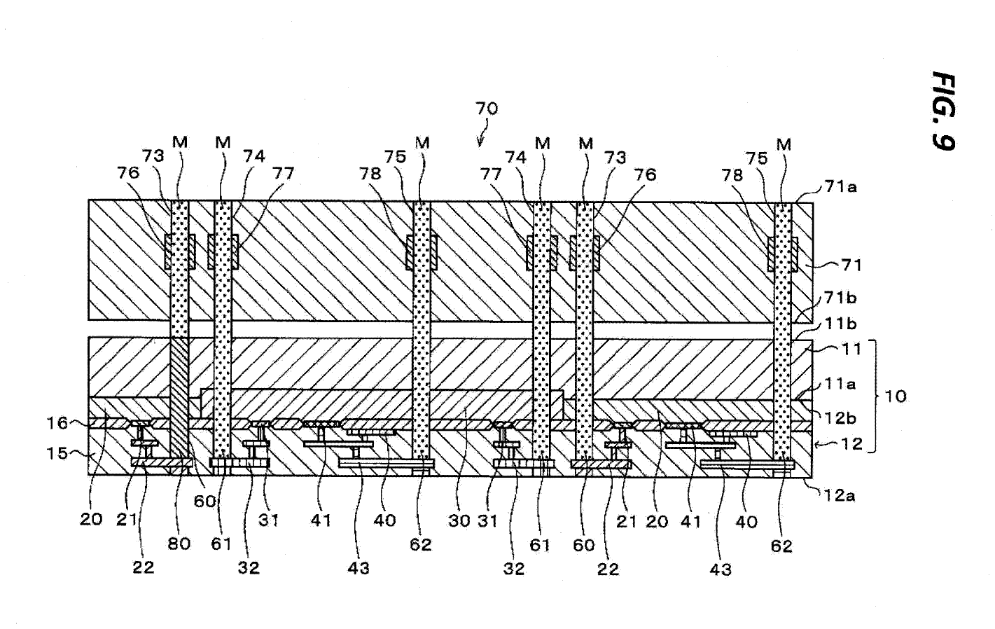

Thereafter, penetration electrodes are formed within the respective through holes 60 to 62. First, descriptions will be made on the case where a penetration electrode is formed within, e.g., the grounding through hole 60. In this case, as illustrated in FIG. 8, a voltage is applied by, e.g., a power source device (not illustrated), using the grounding electrode 76 as a positive electrode and using the power source electrode 77 as a negative electrode. By doing so, a current flows through the grounding electrode 76, the plating solution M existing within the grounding flow path 73 and the grounding through hole 60, the grounding line 22, the P⁺ layer 21, the P-well 20, the N-well 30, the N⁺ layer 31, the power source line 32, the plating solution M existing within the power source through hole 61 and the power source flow path 74, and the power source electrode 77, in the named order (see an arrow in FIG. 8). By virtue of this current, electrolytic plating is performed with respect to the plating solution M existing within the grounding through hole 60. As illustrated in FIG. 9, a penetration electrode 80 is formed within the grounding through hole 60.

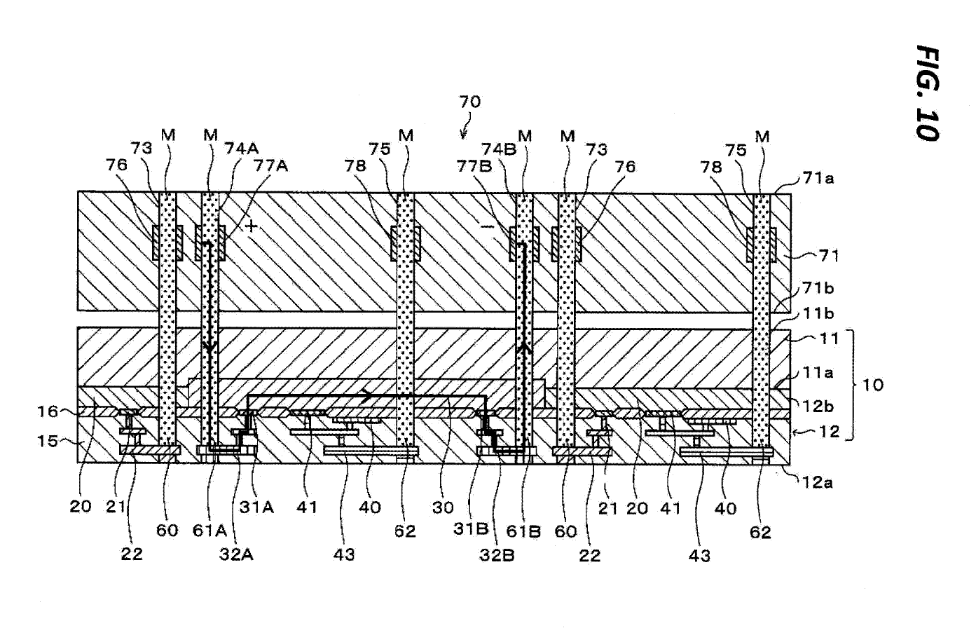

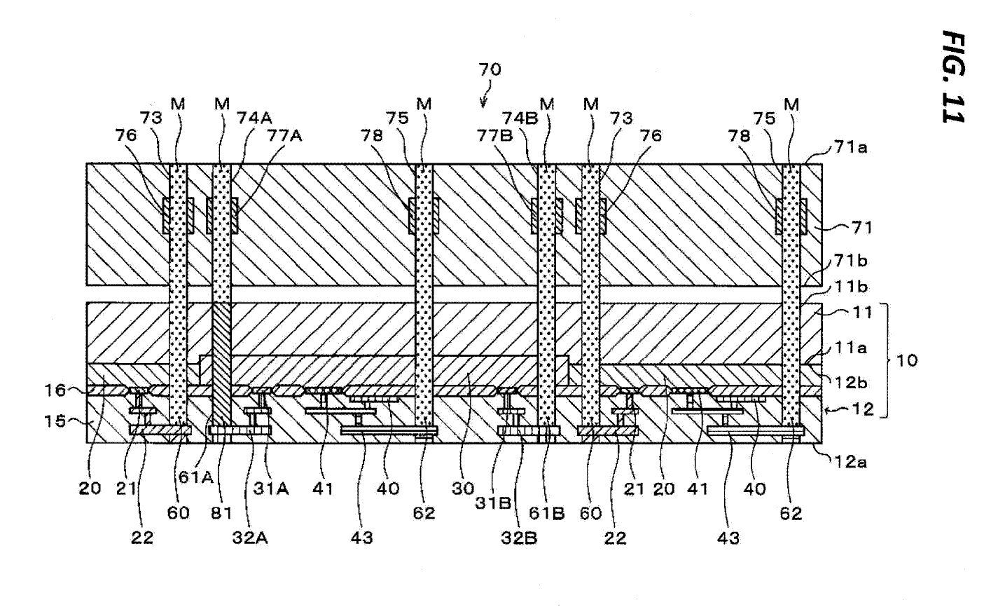

Next, descriptions will be made on the case where a penetration electrode is formed within, e.g., the power source through hole 61. In this case, as illustrated in FIG. 10, a voltage is applied by, e.g., a power source device (not illustrated), using one power source electrode 77A of a pair of power source electrodes 77 and 77 as a positive electrode and using the other power source electrode 77B as a negative electrode. By doing so, a current flows through one power source electrode 77A, the plating solution M existing within one power source flow path 74A and one power source through hole 61A, one power source line 32A, one N⁺ layer 31A, the N-well 30, the other N⁺ layer 31B, the other power source line 32B, the plating solution M existing within the other power source through hole 61B and the other power source flow path 74B, and the other power source electrode 77B in the named order (see an arrow in FIG. 10). By virtue of this current, electrolytic plating is performed with respect to the plating solution M existing within one power source through hole 61A. As illustrated in FIG. 11, a penetration electrode 81 is formed within one power source through hole 61A.

Furthermore, in the case where a penetration electrode is formed within, e.g., the other power source through hole 61B, electrolytic plating is performed by applying a voltage using the other power source electrode 77B as a positive electrode and using one power source electrode 77A as a negative electrode. Thus, a penetration electrode 81 is formed within the other power source through hole 61B.

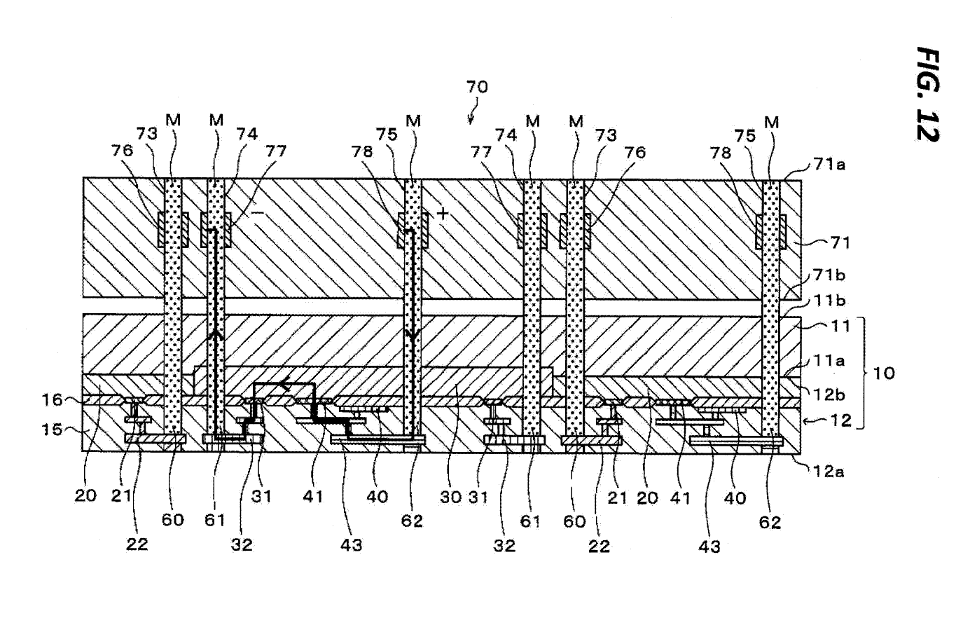

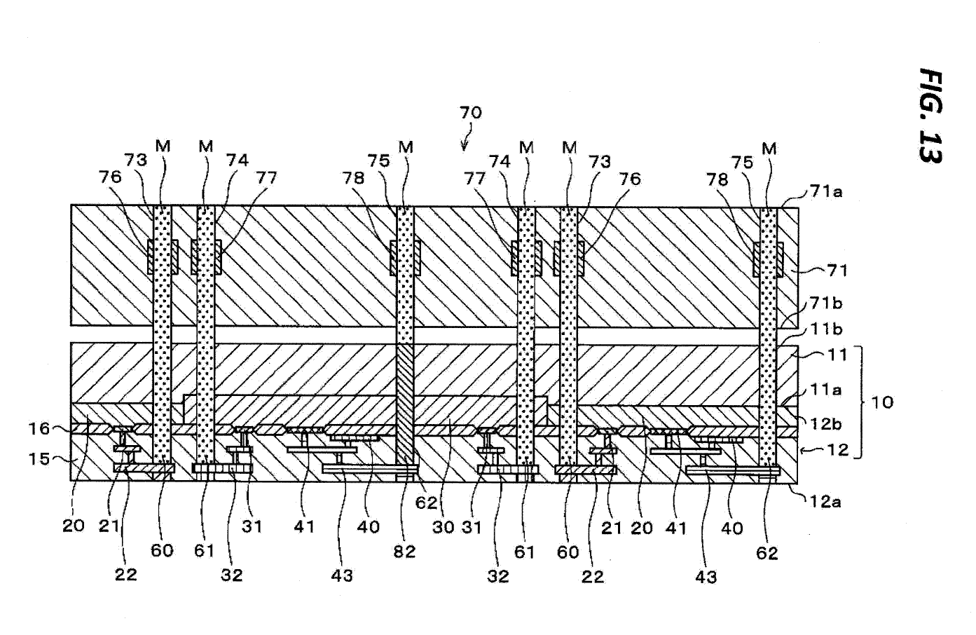

Next, descriptions will be made on, e.g., the case where a penetration electrode is formed within the signal through hole 62 of the P-type MOS transistor 14. In this case, as illustrated in FIG. 12, a voltage is applied by, e.g., a power source device (not illustrated), using the signal electrode 78 corresponding to the P-type MOS transistor 14 as a positive electrode and using the power source electrode 77 as a negative electrode. The voltage used at this time is set depending on the specifications (e.g., the voltage and the pulse width) compensated by the electrostatic protection circuit 41. By doing so, a current flows through the signal electrode 78, the plating solution M existing within the signal flow path 75 and the signal through hole 62, the signal line 43, the electrostatic protection circuit 41, the N-well 30, the N⁺ layer 31, the power source line 32, the plating solution M existing within the power source through hole 61 and the power source flow path 74, and the power source electrode 77, in the named order (see an arrow in FIG. 12). By virtue of this current, electrolytic plating is performed with respect to the plating solution M existing within the signal through hole 62. As illustrated in FIG. 13, a penetration electrode 82 is formed within the signal through hole 62.

Similarly, in the case where a penetration electrode is formed within the signal through hole 62 of, e.g., the N-type MOS transistor 13, electrolytic plating is performed by applying a voltage using the signal electrode 78 as a positive electrode and using the power source electrode 77 as a negative electrode. Thus, a penetration electrode 82 is formed within the signal through hole 62.

In this way, the penetration electrodes 80 to 82 are respectively formed within the through holes 60 to 62 using the manufacturing apparatus 70.

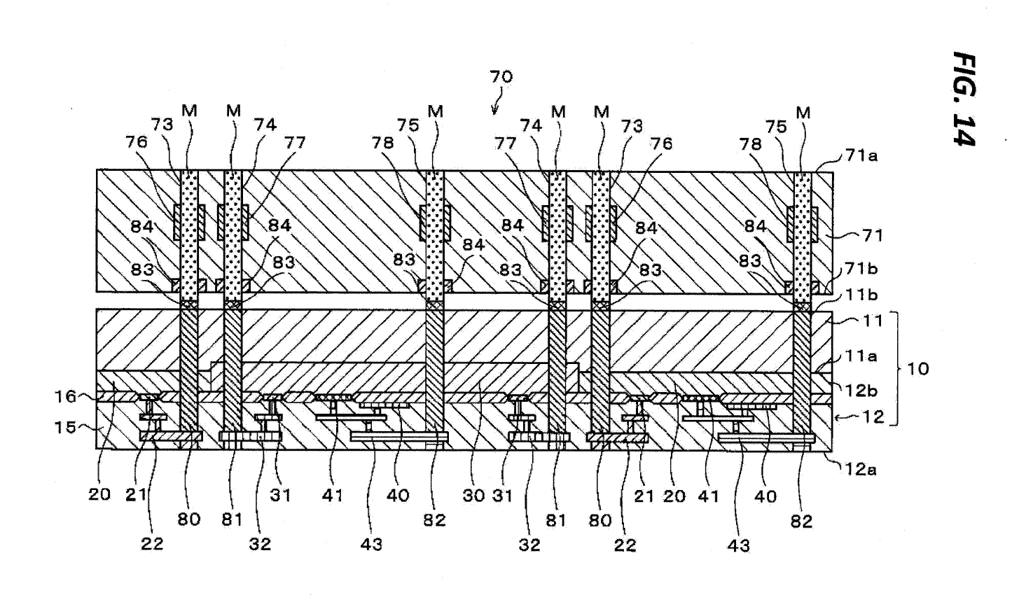

Thereafter, electrolytic plating is further performed with respect to the plating solution M existing on the penetration electrodes 80 to 82. Thus, as illustrated in FIG. 14, bumps 83 are respectively formed on the penetration electrodes 80 to 82. Since the forming method of the bumps 83 is the same as the forming method of the penetration electrodes 80 to 82, the description thereon will be omitted.

Thereafter, an inspection (electrical test) of electrical characteristics of the penetration electrodes 80 to 82 of the wafer 10 and the circuits of the device layer 12 is conducted. In this case, the penetration electrodes 80 to 82 are electrically independent from each other. Therefore, the electrical test may be performed in that state.

The electrical test may be performed in the state where the template 71 is disposed at the side of the rear surface 11b of the wafer 10, using the electrodes 76 to 78 of the template 71 as the electrodes for the electrical test. Alternatively, the electrical test may be performed by installing a plurality of test electrodes 84 in the template 71, bringing the test electrodes 84 into contact with the bumps 83, and sending an electric signal to the penetration electrodes 80 to 82 and the circuits of the device layer 12. In this case, the bumps 83 are plated until the bumps 83 come in contact with the test electrodes 84. The bumps 83 may be welded to the test electrodes 84 by applying a voltage to between the bumps 83 and the test electrodes 84, which enables a stable inspection.

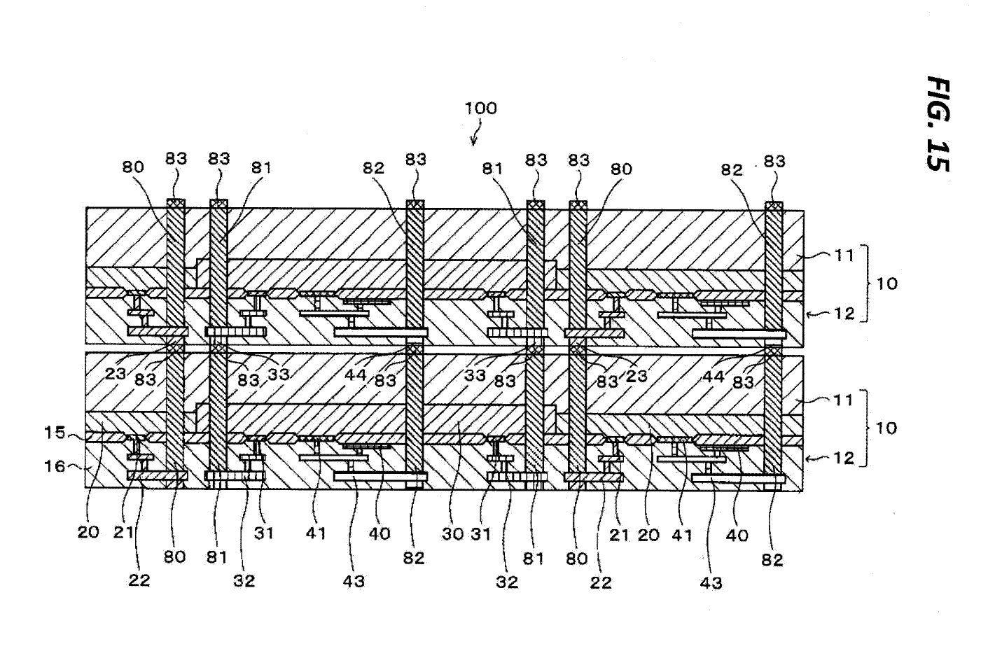

Thereafter, for example, in a wafer bonding device (not illustrated), a plurality of wafers 10 is bonded so that the bumps 23, 33 and 44 of the device layer 12 and the bumps 83 of the penetration electrodes 80 to 82 stacked as illustrated in FIG. 15 are respectively conducted to one another. At this time, the delamination of the wafer 10 and the support substrate 50 is also performed. In this way, there is manufactured a semiconductor device 100 in which the wafers 10 are three-dimensionally laminated.

According to the exemplary embodiment described above, when a voltage is applied using one electrode of the electrodes 76 to 78 of the template 71 as a positive electrode and using the other electrode of the electrodes 76 to 78 of the template 71 as a negative electrode, electrolytic plating may be performed with the plating solution M existing within the through holes 60 to 62 and to form the penetration electrodes 80 to 82 within the through holes 60 to 62. As described above, according to the present exemplary embodiment, there is no need to install an opposite electrode at the wafer side as is the case in the prior art. Therefore, the configuration of the manufacturing apparatus 70 may be simplified and the manufacturing cost of the semiconductor device 100 may be reduced.

Moreover, the penetration electrodes 80 to 82 may be formed only within the through holes 60 to 62, which enables omission of the step of removing the plated layer formed in the portions other than the inside of the through holes by chemical mechanical polishing as is the case in the prior art. Accordingly, the throughput of the plating process may be improved.

Furthermore, as mentioned above, there is no need to install an opposite electrode common to the penetration electrodes 80 to 82 (in the plating solution M existing within the through holes 60 to 62). Therefore, the penetration electrodes 80 to 82 may be electrically independent from each other. In that state, an electrical test for the penetration electrodes 80 to 82 of the wafer 10 and the circuits of the device layer 12 may be performed. Accordingly, the step of removing an opposite electrode when conducting an electrical test as is the case in the prior art may be omitted and the throughput of the manufacturing process of the semiconductor device 100 may be improved.

Furthermore, when performing the electrolytic plating, the positive electrode and the negative electrode may be arbitrarily selected depending on which one of the penetration electrodes 80 to 82 is formed. When forming the penetration electrode 80 within the grounding through hole 60, a voltage may be applied using the grounding electrode 76 as a positive electrode and using the power source electrode 77 as a negative electrode. In the case where the penetration electrode 81 is formed within the power source through hole 61, a voltage may be applied using one power source electrode 77 as a positive electrode and using the other power source electrode 77 as a negative electrode. In the case where the penetration electrode 82 is formed within the signal through hole 62, a voltage may be applied using the signal electrode 78 as a positive electrode and using the power source electrode 77 as a negative electrode. Particularly, in the case of forming the penetration electrode 82, even if a pair of signal through holes 62 and 62 does not exist and only one signal through hole 62 exists, the penetration electrode 82 may be formed using the electrostatic protection circuit 41 of the wafer 10. Accordingly, the present invention is very useful.

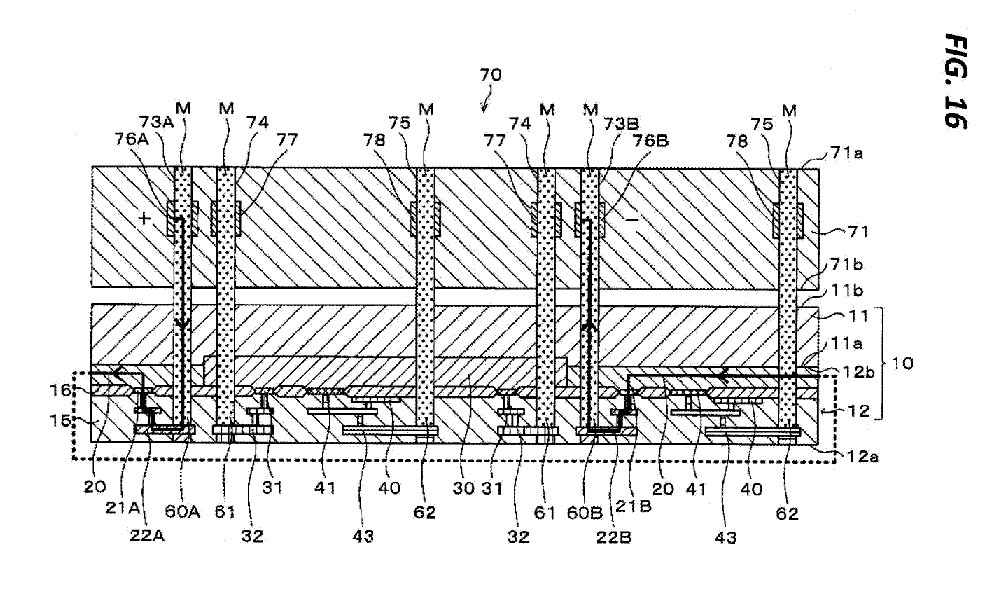

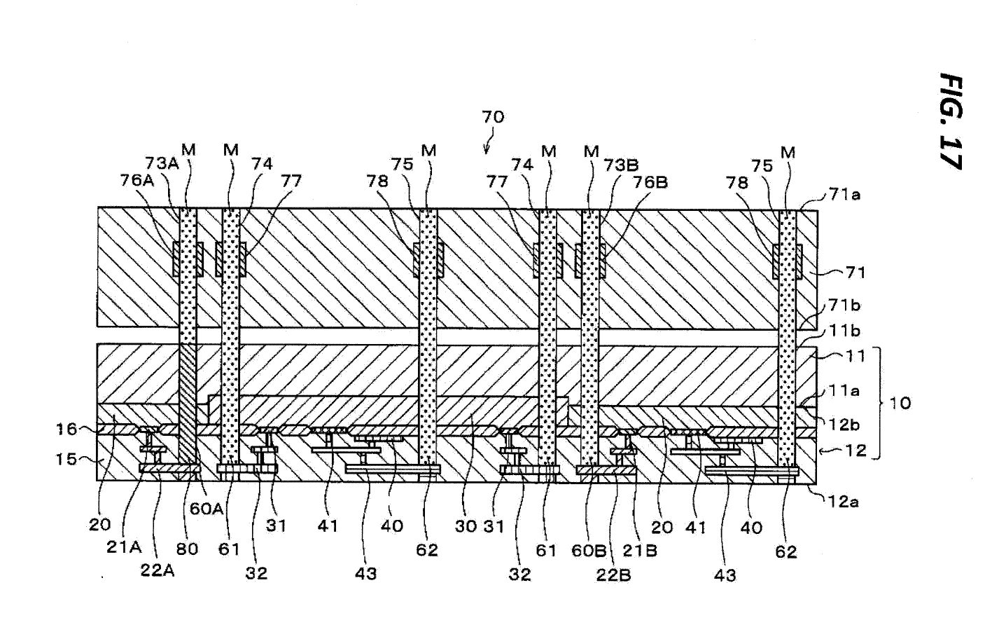

In the above exemplary embodiment, when forming the penetration electrode 80 within the grounding through hole 60, a voltage is applied using the grounding electrode 76 as a positive electrode and using the power source electrode 77 as a negative electrode. However, the positive electrode and the negative electrode may be other electrodes. For example, as illustrated in FIG. 16, a voltage may be applied using one grounding electrode 76A of a pair of grounding electrodes 76 and 76 as a positive electrode and using the other grounding electrode 76B as a negative electrode. By doing so, a current flows through one grounding electrode 76A, the plating solution M existing within one grounding flow path 73A and one grounding through hole 60A, one grounding line 22A, one P⁺ layer 21A, the P-well 20 (or the bulk layer 11), the other P⁺ layer 21B, the other grounding line 22B, the plating solution M existing within the other grounding through hole 60B and the other grounding flow path 73B, and the other power source electrode 76B in the named order (see an arrow in FIG. 16). By virtue of this current, electrolytic plating is performed with respect to the plating solution M existing within one grounding through hole 60A. Thus, a penetration electrode 80 may be formed within one grounding through hole 60A as illustrated in FIG. 17.

Furthermore, in the case where a penetration electrode is formed within, e.g., the other grounding through hole 60B, electrolytic plating is performed by applying a voltage using the other grounding electrode 76B as a positive electrode and using one grounding electrode 76A as a negative electrode. Thus, a penetration electrode 80 may be formed within the other grounding through hole 60B.

Moreover, in the case where a penetration electrode 80 is formed within, e.g., the grounding through hole 60, electrolytic plating is performed by applying a voltage using the grounding electrode 76 as a positive electrode and using the signal electrode 78 as a negative electrode. Thus, a penetration electrode 80 may be formed within the grounding through hole 60.

Even in the present exemplary embodiment, the same effects as those of the aforementioned exemplary embodiment may be achieved. That is, the configuration of the manufacturing apparatus 70 may be simplified and the manufacturing cost of the semiconductor device 100 may be reduced. Further, the throughput of the manufacturing process of the semiconductor device 100 may be improved.

In the above exemplary embodiment, when forming the penetration electrode 82 within the signal through hole 62, a voltage is applied using the signal electrode 78 as a positive electrode and using the power source electrode 77 as a negative electrode. However, the electrodes may be appropriately selected as long as the diode does not come into a reverse bias state within the electrostatic protection circuit 41. When the diode within the electrostatic protection circuit 41 is brought into a forward bias state, a current flows properly, which enables the same processing to be performed.

In the case where the penetration electrode 82 is formed within the signal through hole 62 in the above exemplary embodiment, a penetration electrode 80 may be previously formed within the grounding through hole 60 and a penetration electrode 81 may be formed within the power source through hole 61.

In the above exemplary embodiment, the penetration electrode 82 formed within the signal through hole 62 is a penetration electrode for an input signal. However, the present invention may be applied to the case where a penetration electrode for an output signal is formed within a through hole.

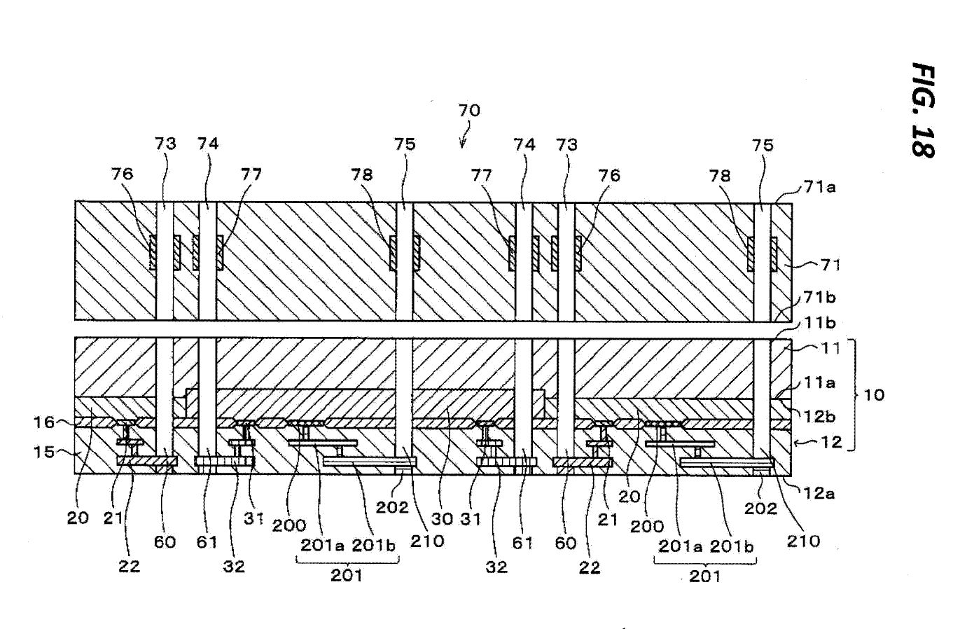

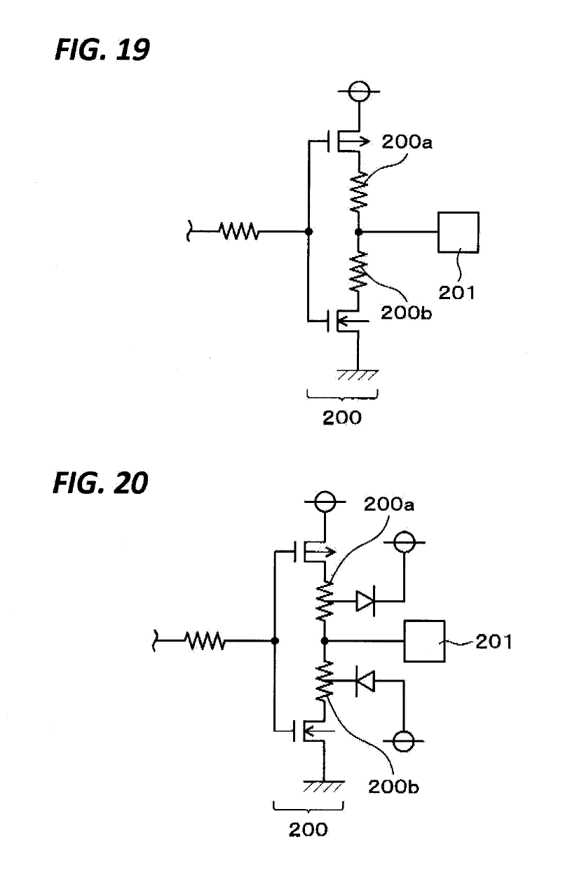

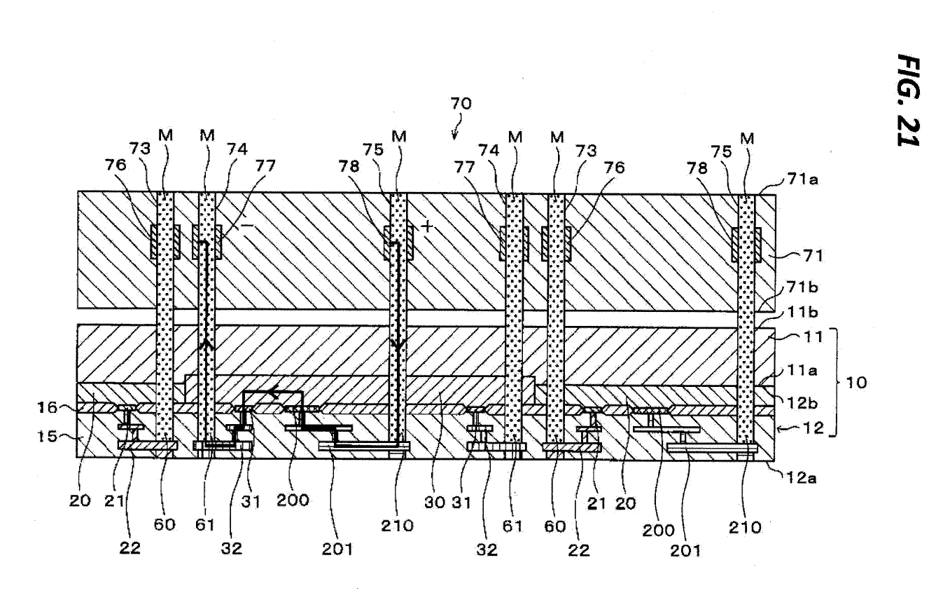

As illustrated in FIG. 18, each of the N-type MOS transistor 13 and the P-type MOS transistor 14 includes an output circuit 200 formed in the insulation film 15 (in the P-well 20 or the N-well 30). In the output circuit 200, as illustrated in FIG. 19, a P⁺ diffusion resistor 200a is provided between the power source side drain of the output circuit 200 and the signal line 201 to be described later, and an N⁺ diffusion resistor 200b is installed between the ground side drain of the output circuit 200 and the signal line 201. The P⁺ diffusion resistor 200a of the drain of the P-type MOS transistor 14 is formed within the N-well 30. The N-well 30 is connected to the power source line 32. As illustrated in FIG. 20, the P⁺ diffusion resistor 200a and the N-well 30 serve as protection diodes for suppressing electrostatic discharge. Furthermore, the N⁺ diffusion resistor 200b of the drain of the N-type MOS transistor 13 is formed within the P-well 20. The P-well 20 is connected to the grounding line 22. The N⁺ diffusion resistor 200b and the P-well 20 serve as protection diodes. The output circuit 200 serves as an electrostatic protection circuit in the present invention.

As illustrated in FIG. 18, a signal line 201 formed in the insulation film 15 is connected to the output circuit 200. The signal line 201 includes a first metal 201a connected to the output circuit 200 via a wiring line and a second metal 201b connected to the first metal 201a via a wiring line. The second metal 201b is connected to a bump 202 exposed on the front surface 12a of the device layer 12.

When forming the grounding through hole 60 and the power source through hole 61 in the wafer 10, a signal through hole 210 similar to the signal through hole 62 of the aforementioned exemplary embodiment is formed.

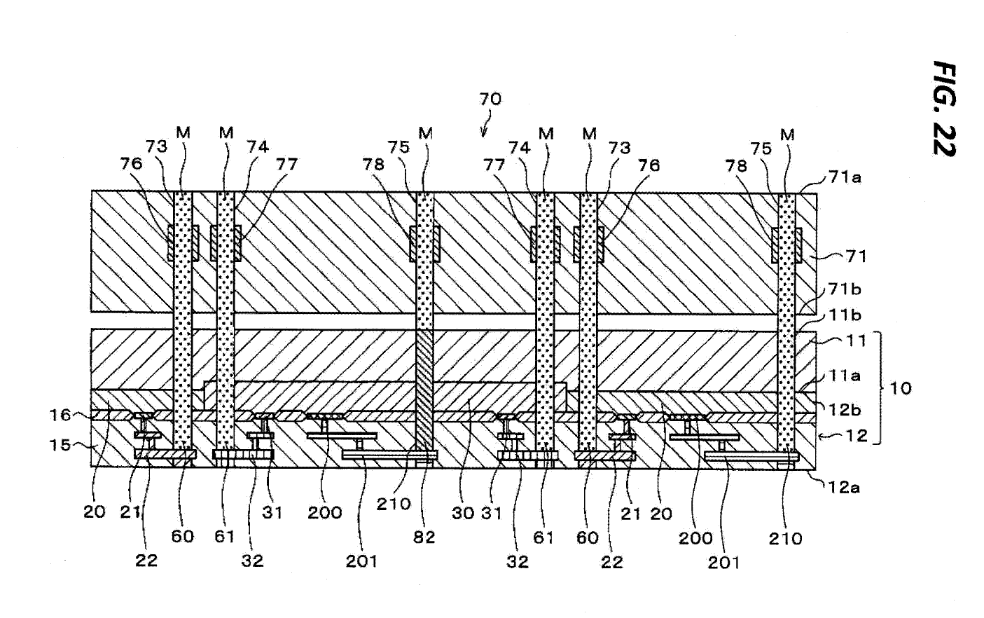

Thereafter, as illustrated in FIG. 21, a plating solution M is supplied to the through holes 60, 61, and 210 through the flow paths 73 to 75 of the template 71. Thereafter, a voltage is applied by, e.g., a power source device (not illustrated), using the signal electrode 78 corresponding to the P-type MOS transistor 14 as a positive electrode and using the power source electrode 77 as a negative electrode. By doing so, a current flows through the signal electrode 78, the plating solution M existing within the signal flow path 75 and the signal through hole 210, the signal line 201, the output circuit 200, the N-well 30, the N⁺ layer 31, the power source line 32, the plating solution M existing within the power source through hole 61 and the power source flow path 74, and the power source electrode 77 in the named order (see an arrow in FIG. 21). By virtue of this current, electrolytic plating is performed with respect to the plating solution M existing within the signal through hole 210. As illustrated in FIG. 22, a penetration electrode 82 is formed within the signal through hole 210.

Similarly, in the case where a penetration electrode is formed within, e.g., the signal through hole 210 of the N-type MOS transistor 13, electrolytic plating is performed by applying a voltage using the signal electrode 78 as a positive electrode and using the power source electrode 77 as a negative electrode. A penetration electrode 82 is formed within the signal through hole 210.

Even in the present exemplary embodiment, the same effects as those of the aforementioned exemplary embodiment may be achieved. That is, the configuration of the manufacturing apparatus 70 may be simplified and the manufacturing cost of the semiconductor device 100 may be reduced. Further, the throughput of the manufacturing process of the semiconductor device 100 may be improved.

In the above exemplary embodiment, when forming the penetration electrode 82 within the signal through hole 210, a voltage is applied using the signal electrode 78 as a positive electrode and using the power source electrode 77 as a negative electrode. However, the electrodes may be appropriately selected as long as the diodes is not brought into a reverse bias state in the output circuit 200 and the P-well 20 or the N-well 30. When the diodes of the output circuit 200 and the P-well 20 or the N-well 30 are brought into a forward bias state, a current flows properly, which enables the same processing to be performed.

In the case where the penetration electrode 82 is formed within the signal through hole 210 in the above exemplary embodiment, a penetration electrode 80 may be previously formed within the grounding through hole 60 and a penetration electrode 81 may be formed within the power source through hole 61.

In the above exemplary embodiment, the penetration electrodes 80 to 82 are formed within the through holes 60 to 62 by applying a voltage via the P-well 20 or the N-well 30 which is a diffusion region. However, the path for applying a voltage is not limited thereto. As an example, when a positive electrode and a negative electrode are connected by a circuit (a circuit unit in the present invention) formed of metal wiring lines in the device layer 12 of the wafer 10 and when a voltage is applied via the circuit, the penetration electrodes 80 to 82 may be formed within the through holes 60 to 62.

In the above exemplary embodiment, descriptions have been made on the case where the penetration electrodes 80 to 82 are formed within the through holes 60 to 62 of the wafer 10 by performing electrolytic plating using the plating solution M as the processing solution. However, the present invention may be applied to other electrolysis processes.

For example, the present invention may be applied to the case where electro-deposition insulation films are formed within the through holes 61 and 62 of the wafer 10. The electro-deposition insulation films are formed on the inner surfaces of the through holes 61 and 62 before the penetration electrodes 81 and 82 are formed within the through holes 61 and 62.

In this case, an electro-deposition insulation film solution as a processing solution, for example, an electro-deposition polyimide solution, is supplied to the through holes 60 to 62 through the flow paths 73 to 75 of the template 71. Then, a voltage is applied using one power source electrode 77 of a pair of power source electrodes 77 and 77 as a positive electrode and using the other power source electrode 77 as a negative electrode. Thus, an electro-deposition insulation film is formed on the inner surface of the power source through hole 61. Furthermore, a voltage is applied using the signal electrode 78 as a positive electrode and using the power source electrode 77 or the grounding electrode 76 as a negative electrode. Thus, an electro-deposition insulation film is formed on the inner surface of the signal through hole 62. There is no need to form an electro-deposition insulation film on the inner surface of the grounding through hole 60. In this case, a voltage may not be applied to between the grounding electrode 76 and the power source electrode 77 as in the above exemplary embodiment or between a pair of grounding electrodes 76 and 76. By selecting the voltage-applied electrodes in this way, electro-deposition insulation films may be selectively formed only on the inner surface of the power source through hole 61 and the inner surface of the signal through hole 62 without forming an electro-deposition insulation film on the inner surface of the grounding through hole 60.

While some preferred exemplary embodiments of the present invention have been described above with reference to the accompanying drawings, the present invention is not limited to such exemplary embodiments. It will be apparent to those skilled in the relevant art that various kinds of modifications or changes may be conceived without departing from the spirit and scope recited in the claims. It is to be understood that such modifications or changes fall within the technical scope of the present invention. The present invention is not limited to the above-described exemplary embodiments and may take a variety of forms.

### DESCRIPTION OF SYMBOLS

10: wafer, 11: bulk layer, 12: device layer, 20: P-well, 22: grounding line, 30: N-well, 32: power source line, 40: input gate, 41: electrostatic protection circuit, 43: signal line, 60: grounding through hole, 61: power source through hole, 62: signal through hole, 70: manufacturing apparatus, 71: template, 72: control unit, 73: grounding flow path, 74: power source flow path, 75: signal flow path, 76: grounding electrode, 77: power source electrode, 78: signal electrode, 80 to 82: penetration electrode, 100: semiconductor device, 200: output circuit, 201: signal line, 210: signal through hole, M: plating solution

What is claimed is:

1. A method for manufacturing a semiconductor device, the method comprising:
a template disposing step at which a template including a plurality of flow paths configured to allow a processing solution to flow therethrough and a plurality of electrodes installed in the flow paths is disposed with respect to a substrate including a plurality of through holes formed therethrough in a thickness direction such that the flow paths correspond to the through holes;
a processing solution supply step at which the processing solution is supplied into the through holes through the flow paths; and
a processing step at which a predetermined processing is performed with respect to the substrate by applying a voltage using one of the electrodes as a positive electrode and using another electrode as a negative electrode.

2. The method of claim 1, wherein the substrate includes a circuit unit configured to interconnect the positive electrode and the negative electrode, and
at the processing step, a voltage is applied to the positive electrode and the negative electrode via the circuit unit.

3. The method of claim 2, wherein the substrate includes a diffusion region, and
at the processing step, a voltage is applied to the positive electrode and the negative electrode via the diffusion region.

4. The method of claim 3, wherein the through holes include a signal through hole for a penetration electrode connected to a signal line, a grounding through hole for a penetration electrode connected to a grounding line, and a power source through hole for a penetration electrode connected to a power source line,
the diffusion region constitutes an electrostatic protection circuit connected between the signal line and the grounding line or the power source line, and
at the processing step, a voltage is applied via the electrostatic protection circuit using the electrode corresponding to one of the signal through hole, the grounding through hole, and the power source through hole as a positive electrode and using the electrode corresponding to another through hole as a negative electrode.

5. The method of claim 1, wherein the through holes include a grounding through hole for a penetration electrode connected to a grounding line, a power source through hole for a penetration electrode connected to a power source line, and a signal through hole for a penetration electrode connected to a signal line, and
at the processing step, a voltage is applied using one electrode corresponding to the grounding through hole as a positive electrode and using another electrode corresponding to the power source through hole or the signal through hole as a negative electrode.

6. The method of claim 1, wherein the through holes include a plurality of grounding through holes for penetration electrodes connected to a grounding line, and
at the processing step, a voltage is applied using one electrode corresponding to one of the grounding through holes as a positive electrode and using another electrode corresponding to another grounding through hole as a negative electrode.

7. The method of claim 1, wherein the through holes include a plurality of power source through holes for penetration electrodes connected to a power source line, and
at the processing step, a voltage is applied using one electrode corresponding to one of the power source through holes as a positive electrode and using another electrode corresponding to another power source through hole as a negative electrode.

8. An apparatus for manufacturing a semiconductor device, the apparatus comprising:
a template including a plurality of flow paths configured to allow a processing solution to flow therethrough and a plurality of electrodes installed in the flow paths; and
a control unit configured to control the template to execute: a template disposing step at which, with respect to a substrate including a plurality of through holes formed therethrough in a thickness direction, the template is disposed such that the flow paths correspond to the through holes; a processing solution supply step at which the processing solution is supplied into the through holes through the flow paths; and a processing step at which a predetermined processing is performed with respect to the substrate by applying a voltage using one of the electrodes as a positive electrode and using another electrode as a negative electrode.

9. The apparatus of claim 8, wherein the substrate includes a circuit unit configured to interconnect the positive electrode and the negative electrode, and
at the processing step, the control unit controls the template to apply a voltage to the positive electrode and the negative electrode via the circuit unit.

10. The apparatus of claim 9, wherein the substrate includes a diffusion region, and
at the processing step, the control unit controls the template to apply a voltage to the positive electrode and the negative electrode via the diffusion region.

11. The apparatus of claim 10, wherein the through holes include a signal through hole for a penetration electrode connected to a signal line, a grounding through hole for a penetration electrode connected to a grounding line, and a power source through hole for a penetration electrode connected to a power source line,
the diffusion region constitutes an electrostatic protection circuit connected between the signal line and the grounding line or the power source line, and
at the processing step, the control unit controls the template to apply a voltage via the electrostatic protection circuit using the electrode corresponding to one of the signal through hole, the grounding through hole and the power source through hole as a positive electrode and using the electrode corresponding to another through hole as a negative electrode.

12. The apparatus of claim 8, wherein the through holes include a grounding through hole for a penetration electrode connected to a grounding line, a power source through hole for a penetration electrode connected to a power source line, and a signal through hole for a penetration electrode connected to a signal line, and
at the processing step, the control unit controls the template to apply a voltage using one electrode corresponding to the grounding through hole as a positive electrode and using another electrode corresponding to the power source through hole or the signal through hole as a negative electrode.

13. The apparatus of claim 8, wherein the through holes include a plurality of grounding through holes for penetration electrodes connected to a grounding line, and
at the processing step, the control unit controls the template to apply a voltage using one electrode corresponding to one of the grounding through holes as a positive electrode and using another electrode corresponding to another grounding through hole as a negative electrode.

14. The apparatus of claim 8, wherein the through holes include a plurality of power source through holes for penetration electrodes connected to a power source line, and
at the processing step, the control unit controls the template to apply a voltage using one electrode corresponding to one of the power source through holes as a positive electrode and using another electrode corresponding to another power source through hole as a negative electrode.
